(19) United States
(12) Patent Application Publication
(10) Pub. No.: US 2025/0143131 A1
(43) Pub. Date: May 1, 2025

(54) DISPLAY PANEL AND DISPLAY DEVICE

(71) Applicant: Hubei Yangtze Industrial Innovation Center of Advanced Display Co., LTD., Wuhan (CN)

(72) Inventor: Liang HU, Wuhan (CN)

(21) Appl. No.: 18/622,633

(22) Filed: Mar. 29, 2024

(30) Foreign Application Priority Data
Oct. 27, 2023 (CN) 202311421863.1

(51) Int. Cl. H10K 59/38; H10K 59/126

(52) U.S. Cl. CPC H10K 59/38; H10K 59/126

(57) ABSTRACT

A display panel includes a display region and a non-display region adjacent to the display region. The non-display region includes a boundary marking region that includes a marking structure. The display panel further includes a substrate; a light-shielding layer on the substrate and located in the display region and the non-display region; a color blocking structure arranged corresponding to the light-shielding layer openings and located in the display region; a first functional layer; and a second functional layer. The light-shielding layer includes light-shielding layer openings. The first functional layer and the second functional layer are arranged on a side of the light-shielding layer away from the substrate. There is an interface between the first functional layer and the second functional layer, including a first portion and a second portion. The second portion is distributed corresponding to the boundary marking region, and is not coplanar with the first portion.

### CROSS-REFERENCE TO RELATED APPLICATION

This application claims the priority of Chinese Patent Application No. 202311421863.1, filed on Oct. 27, 2023, the content of which is incorporated herein by reference in its entirety.

### TECHNICAL FIELD

The present disclosure generally relates to the field of electronic product technology and, more particularly, relates to a display panel and a display device.

### BACKGROUND

For display panels, POL-less technologies are often used by replacing a polarizer (POL) with a color filter (CF). A circular polarizer is substituted by a black matrix and a filter structure, to reduce a luminous flux of ambient light entering the display panel. However, because of structural limitations of the existing display panels, it is difficult to identify a boundary of a display region in a display panel, which is not conducive to the precise fit of a display panel cover.

### SUMMARY

One aspect of the present disclosure provides a display panel. The display panel has a display region and a non-display region adjacent to the display region. The non-display region includes a boundary marking region and the boundary marking region includes a marking structure. The display panel includes a substrate; a light-shielding layer on a side of the substrate and located in the display region and the non-display region; a color blocking structure arranged corresponding to the light-shielding layer openings and located in the display region; a first functional layer; and a second functional layer. The light-shielding layer includes light-shielding layer openings in the display region. The first functional layer and the second functional layer are arranged on a side of the light-shielding layer away from the substrate in a direction away from the substrate. There is an interface between the first functional layer and the second functional layer. The interface includes a first portion and a second portion. The second portion is distributed corresponding to the boundary marking region; and the second portion is not coplanar with the first portion.

Another aspect of the present disclosure provides a display device. The display device includes a display panel. The non-display region includes a boundary marking region and the boundary marking region includes a marking structure. The display panel includes a substrate; a light-shielding layer on a side of the substrate and located in the display region and the non-display region; a color blocking structure arranged corresponding to the light-shielding layer openings and located in the display region; a first functional layer; and a second functional layer. The light-shielding layer includes light-shielding layer openings in the display region. The first functional layer and the second functional layer are arranged on a side of the light-shielding layer away from the substrate in a direction away from the substrate. There is an interface between the first functional layer and the second functional layer. The interface includes a first portion and a second portion. The second portion is distributed corresponding to the boundary marking region; and the second portion is not coplanar with the first portion.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a structural diagram of an exemplary display panel consistent with various disclosed embodiments of the present disclosure.

FIG. 2 illustrates a cross-sectional view of an exemplary display panel in FIG. 1 along a B-B direction, consistent with various disclosed embodiments of the present disclosure.

FIG. 3 illustrates a cross-sectional view of another exemplary display panel in FIG. 1 along a B-B direction, consistent with various disclosed embodiments of the present disclosure.

FIG. 4 illustrates a light path of an exemplary display panel under external light consistent with various disclosed embodiments of the present disclosure.

FIG. 5 illustrates a cross-sectional view of another exemplary display panel in FIG. 1 along a B-B direction, consistent with various disclosed embodiments of the present disclosure.

FIG. 6 illustrates a cross-sectional view of another exemplary display panel in FIG. 1 along a B-B direction, consistent with various disclosed embodiments of the present disclosure.

FIG. 7 illustrates a cross-sectional view of another exemplary display panel in FIG. 1 along a B-B direction, consistent with various disclosed embodiments of the present disclosure.

FIG. 8 illustrates a cross-sectional view of another exemplary display panel in FIG. 1 along a B-B direction, consistent with various disclosed embodiments of the present disclosure.

FIG. 9 illustrates a cross-sectional view of another exemplary display panel in FIG. 1 along a B-B direction, consistent with various disclosed embodiments of the present disclosure.

FIG. 10 illustrates a cross-sectional view of another exemplary display panel in FIG. 1 along a B-B direction, consistent with various disclosed embodiments of the present disclosure.

FIG. 11 illustrates a cross-sectional view of another exemplary display panel in FIG. 1 along a B-B direction, consistent with various disclosed embodiments of the present disclosure.

FIG. 12 illustrates a cross-sectional view of another exemplary display panel in FIG. 1 along a B-B direction, consistent with various disclosed embodiments of the present disclosure.

FIG. 13 illustrates a cross-sectional view of another exemplary display panel in FIG. 1 along a B-B direction, consistent with various disclosed embodiments of the present disclosure.

FIG. 14 illustrates a cross-sectional view of another exemplary display panel in FIG. 1 along a B-B direction, consistent with various disclosed embodiments of the present disclosure.

FIG. 15 illustrates a partially enlarged view of at point C of an exemplary display panel in FIG. 1, consistent with various disclosed embodiments of the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, relational terms such as first and second are only used to distinguish one entity or operation from another entity or operation, and do not necessarily require or imply any such actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region.

In the present disclosure, the term “electrical connection” refers to that two components are directly electrically connected with each other, or the two components are electrically connected via one or more other components.

Exemplary embodiments of a display module and a display device including a display module have been specifically described herein, many modifications and changes may be made and will be apparent to those skilled in the art. Accordingly, it will be understood that display modules constructed in accordance with the principles of the present disclosure and display devices including the display modules may be implemented other than what is specifically described herein. The present disclosure is also limited to claims and their equivalents.

In a display panel in existing technologies, a circular polarizer is substituted by a black matrix and a filter structure, to reduce the luminous flux of ambient light entering the display panel. However, because of the introduction of the black matrix, film layers under the black matrix are blocked and it is difficult to identify a boundary of a display region in the display panel. Therefore, accurate attachment of a display panel cover is hard to ensure.

The present disclosure provides a display panel and a display device, to at least partially alleviate the above problems. In the present disclosure, a marking structure may be introduced in such a way that a first portion and a second portion of an interface between a first functional layer and a second functional layer are not coplanar. Therefore, reflection effects produced by external light irradiated at the first portion and the second portion may be different, which may be used to determine a boundary position between the display region and the non-display region. Correspondingly, the visibility of the boundary of the display region in the display panel in the subsequent cover attachment process may be improved.

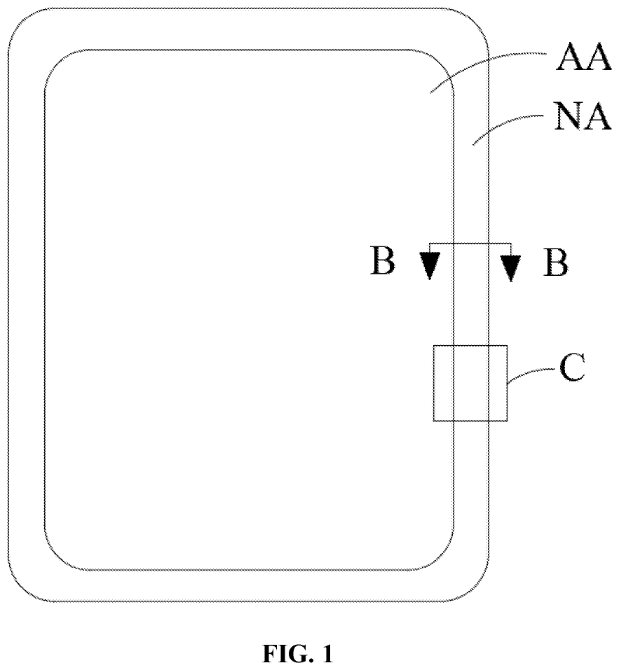

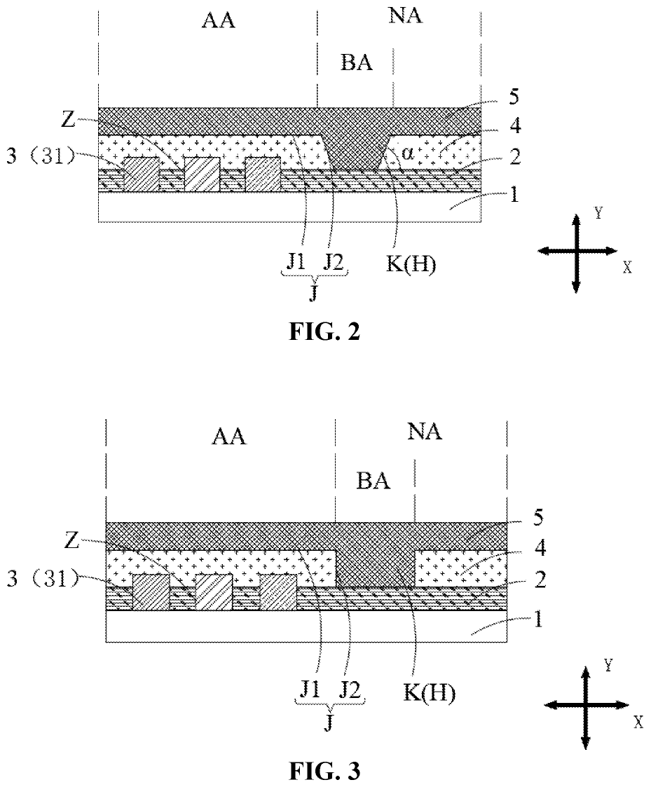

The present disclosure provides a display panel. In one embodiment shown in FIG. 1 which is a structure of an exemplary display panel provided by the present disclosure and FIG. 2 is a cross-sectional view of the display panel along a B-B direction in FIG. 2, the display panel may have a display region AA and a non-display region NA adjacent to each other. The non-display region NA may include a boundary marking region BA, and the boundary marking region BA may be provided with a marking structure H. The display panel may include: a substrate 1; a light-shielding layer 2 on one side of the substrate 1 and located in the display region AA and the non-display region NA, color blocking structures 3, a first functional layer 4, and a second functional layer 5. In the display region AA, the light-shielding layer 2 may have light-shielding layer openings Z; and the color blocking structures 3 may be arranged corresponding to the light-shielding layer openings Z. The color blocking structures 3 may be located in the display region AA. The first functional layer 4 and the second functional layer 5 may be stacked on a side of the light-shielding layer 2 away from the substrate 1 along a direction away from the substrate 1. There may be an interface J between the first functional layer 4 and the second functional layer 5. The interface J may include a first portion J1 and a second portion J2. The second portion J2 may be disposed corresponding to the boundary marking region BA. The second portion J2 and the first portion may be not coplanar.

In the present disclosure, the display panel may include the substrate 1, the light-shielding layer 2, the color blocking structures 3, the first functional layer 4 and the second functional layer 5. The marking structure H may be provided in the boundary marking region BA of the display panel. By setting the marking structure H such that the second portion J2 and the first portion J1 of the interface J between the first functional layer 4 and the second functional layer 5 are not coplanar, the optical paths of the reflected light when the external light irradiates the second portion J2 and the first portion J1 may be different. Correspondingly, under external observation, for example, under the observation of human eyes, the amount of reflected light generated by the second portion J2 and the first portion J1 and entering the human eyes may be also different, and brightness/darkness levels of the display panel at the second portion J2 and the first portion J1 may be different visually. The second portion J2 may be disposed corresponding to the boundary marking region BA. Therefore, by identifying the difference in the brightness/darkness levels between the second portion J2 and the first portion J1 under external observation, the boundary position between the display region AA and the non-display region NA may be determined, improving the visibility of the boundary of the display region AA in the display panel in the subsequent attachment process of a cover 8.

In one embodiment, the second portion J2 may be disposed corresponding to the boundary marking region BA, which, for example, may be regarded as that an region where the second portion J2 of the interface J (the interface J being between the first functional layer 4 and the second functional layer 5) is located defines the boundary marking region BA. The marking structure H may adopt a structural form, such as a convex structure or a groove structure, such that the second portion J2 is convex or recessed relative to the first portion J1, and the second portion J2 and the first portion J1 are not coplanar with each other. Correspondingly, the brightness/darkness levels at the second portion J2 and the first portion J1 may be different visually under external observation.

The substrate 1 may be a hard substrate, such as a glass substrate. In some other embodiments, the substrate 1 may also be a flexible substrate, and may be made of a material including polyimide, polystyrene, polyethylene terephthalate, poly(para-xylene), polyether sulfone or polyethylene naphthalate. The substrate 1 may be mainly used to support devices arranged on the substrate 1.

The color blocking structures 3 may be used to filter light to emit light of different colors. For example, the incoming light of a color blocking structure 3 may be white light, and the light may be filtered into red light after passing through the color blocking structure 3 which is a red color blocker 31, that is, the emitted light may be red light. The color blocking structures 3 of other colors may work similarly.

The first functional layer 4 and the second functional layer 5 may be any of an optical adhesive layer, a planarization layer, or other film layers in the display panel. For example, in one embodiment, the first functional layer 4 and the second functional layer 5 may both be transparent optical adhesive layers. Since the first functional layer 4 is disposed on the side of the color blocking structures 3 away from the substrate 1, the first functional layer 4 may protect and planarize the color blocking structures 3, while the second functional layer 5 may play a role in bonding effect. For example, in one embodiment, the first functional layer 4 may be made of a material including optically clear photoresist (OC), and the second functional layer 5 may be made of a material including optically clear adhesive (OCA). Of course, in other embodiments, the first functional layer 4 and the second functional layer 5 may also be other film layers of the display panel, and are not particularly limited in the present disclosure.

In one embodiment shown in FIG. 2 and FIG. 3 which is another cross-sectional view of the display panel along the B-B direction in FIG. 1, the marking structure H may include a groove K provided on the first functional layer 4, and the second functional layer 5 may fill the groove K.

In this embodiment, a portion of the first functional layer 4 may be removed to form the groove K, and then the second functional layer 5 may be formed on the side of the first functional layer 4 away from the substrate 1, and a portion of the second functional layer 5 may be filled in the groove K. In this embodiment, a portion of the interface J between a portion of the first functional layer 4 corresponding to the side of the groove K and the second functional layer 5 may be regarded as the second portion J2, and another portion of the interface J between another portion of the first functional layer 4 without the groove K and the second functional layer 5 may be regarded as the first portion J1. By setting the groove K, the second portion J2 and the first portion J1 may not be coplanar with each other. The angle between the second portion J2 and the first portion J1 may be determined by the inclination angle of the side of the groove K relative to the plane of the substrate 1.

In one embodiment, the groove K provided in the first functional layer 4 may penetrate through the entire first functional layer 4. In some other embodiment, the groove K provided in the first functional layer 4 may not penetrate through the entire first functional layer 4, that is, the groove K may adopt a structural form similar to a blind hole. The structure of the groove may be selected according to actual needs, and is not specially limited in the present disclosure.

As shown in FIG. 2, in one embodiment, along a direction from the substrate 1 to the first functional layer 4, the groove K may be gradually expanded.

In this embodiment, the groove K may be gradually expanded, that is, at the side of the groove K facing the display surface of the display panel, external light may directly irradiate to the side of the groove K. Therefore, the optical paths of the reflective light when the external light irradiates to a portion of the first functional layer 4 corresponding to the side of the groove K and another portion of the first functional layer 4 without the groove K may be different, making it easier to identify the difference in brightness/darkness levels of the first portion J1 corresponding to the position of the groove K and the second portion J2 under external observation.

For example, in some embodiments, in the direction Y perpendicular to the plane of the substrate 1, the cross-section of the groove K may be an inverted trapezoid (as shown in FIG. 2), a triangle, or another gradually expanding shape. Of course, according to actual needs, in other embodiments, the cross-section of the groove K may be another suitable shape, such as a rectangle (as shown in FIG. 3), which may be formed easily.

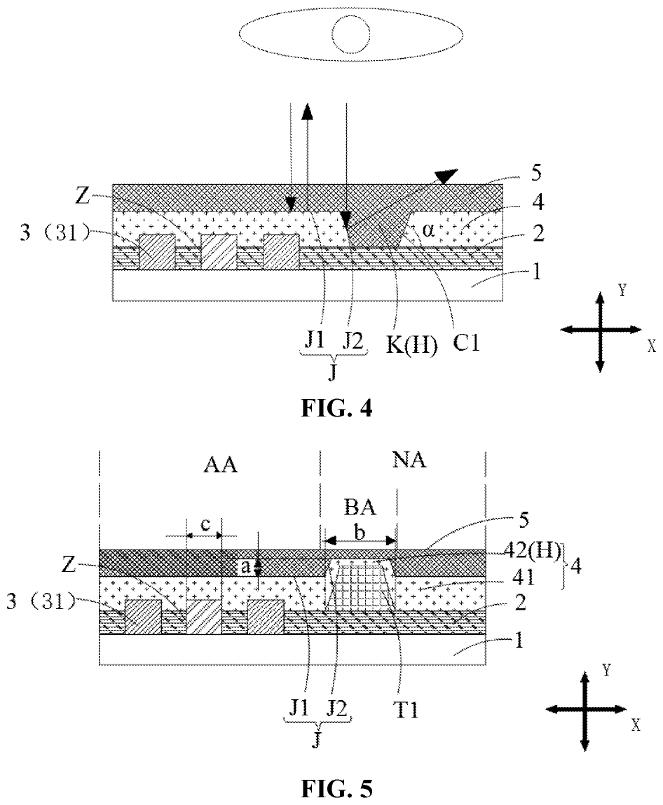

In one embodiment shown in FIG. 4 illustrating a schematic diagram of the optical paths when the external light is irradiated to the display panel, the groove K may include a first side, and an angle α between the first side and the plane of the substrate 1 may be from 60° to 90°.

The angle between the first side C1 and the plane of the substrate 1 may affect the reflection effect of the first side C1 under external light irradiation. When the angle between the first side C1 and the plane of the substrate 1 is larger, the difference between the reflective effect when the external light is irradiated to the first side C1 and when the external light is irradiated to the portion of the first functional layer 4 without the groove K may be more obvious. That is, when the angle between the first side C1 and the plane of the substrate 1 is larger, the amount of external light reflected at the first side C1 that enters the human eyes may be less and the first side C1 may be darker visually. Therefore, it may be easier for the human eye to identify the boundary of the first side C1.

In one embodiment, the angle between the first side C1 and the plane of the substrate 1 may be 90°, and the cross section of the groove K correspondingly may be a rectangle. In other embodiments, the angle between the first side C1 and the plane of the substrate 1 may be any one of 60°, 70°, 80°, or 90°.

In one embodiment, the refractive index of the first functional layer 4 may be smaller than the refractive index of the second functional layer 5. When difference between the refractive index of the first functional layer 4 and the refractive index of the second functional layer 5 is smaller, the amount of external light reflected at the first side C1 that enters the human eyes may be less and the first side C1 may be darker visually. Therefore, it may be easier for the human eye to identify the boundary of the first side C1.

In one embodiment, the difference in refractive index between the first functional layer 4 and the second functional layer 5 may be less than or equal to 0.1. For example, in one embodiment, the refractive index of the first functional layer 4 may be 1.5, and the refractive index of the second functional layer 5 may be 1.6.

In one embodiment shown in FIG. 5, which is another cross-sectional view of the display panel along the B-B direction in FIG. 1, a first protruding structure T1 may be provided on a side of the light-shielding layer 2 away from the substrate 1. The first protruding structure T1 may be located in the boundary marking region BA. The first functional layer 4 may include a flat portion 41 and a raised portion 42 on a side of the first protruding structure T1 away from the substrate 1. The raised portion 42 may protrude relative to the flat portion 41 along the direction away from the substrate 1. The marking structure H may include the raised portion 42.

In the present embodiment, since the first functional layer 4 is usually prepared as a whole layer, the raised portion 42 may be formed at a position corresponding to the first protruding structure T1 when forming the first functional layer 4 after the first protruding structure T1 is provided. Correspondingly, the interface J between the raised portion 42 and the second functional layer 5 may correspond to the second portion J2, and the interface J between the flat portion 41 and the second functional layer 5 may correspond to the first portion J1. Since the raised portion 42 protrudes relative to the flat portion 41, the interface J between the raised portion 42 and the second functional layer 5 and the interface J between the flat portion 41 and the second functional layer 5 may be not coplanar with each other, such that the optical paths of the reflected light when the external light irradiates to the raised portion 42 and the flat portion 41 may be different. Therefore, the amount of reflective light entering the human eye generated by the external light irradiated to the first portion J1 and the second portion J2 may be different, and it may be easier to identify the difference of the brightness/darkness levels of the second portion J2 corresponding to the raised portion 42 and the first portion J1 under external light irradiation.

As shown in FIG. 5, in some embodiments, in the direction from the substrate 1 to the first functional layer 4, the first protruding structure T1 may be tapered. Since the raised portion 42 of the first functional layer 4 is formed corresponding to the first protruding structure T1, when the first protruding structure T1 is tapered, the raised portion 42 of the first functional layer 4 may be also tapered accordingly. Correspondingly, at the side of the raised portion 42 facing the display surface of the display panel, the external light may directly illuminate the side of the raised portion 42. Correspondingly, the optical paths of the reflected light when the external light is irradiated to a portion of the first function layer 4 corresponding to the side of the raised portion 42 and another portion of the first functional layer 4 without the raised portion 42 may be different. Therefore, the amount of reflective light entering the human eye generated by the external light irradiated to the first portion J1 and the second portion J2 may be different, and it may be easier to identify the difference of the brightness/darkness levels of the second portion J2 corresponding to the raised portion 42 and the first portion J1 under external light irradiation.

As shown in FIG. 5, in some optional embodiments, in the direction Y perpendicular to the plane where the substrate 1 is located, a height difference a between a surface of a side of the raised portion 42 away from the substrate 1 and a surface of a side of the flat portion 41 away from the substrate 1 may be larger than or equal to 1.5 μm.

When the protruding height of the raised portion 42 relative to the flat portion 41 is higher, the difference between the brightness/darkness level of the raised portion 42 and the flat portion 41 under external light irradiation may be higher and may be easier to identify. Therefore, in this embodiment, when the height difference a between the surface of the side the raised portion 42 away from the substrate 1 and the surface of the side of the flat portion 41 away from the substrate 1 is larger than or equal to 1.5 μm, the grayscale difference between the first portion J1 and the second portion J2 may be able to be easily identified, to determine the boundary position between the display region AA and the non-display region NA. For example, the height difference a between the surface of the side of the raised portion 42 away from the substrate 1 and the surface of the side of the flat portion 41 away from the substrate 1 may be set to 1.5 μm, 1.6 μm, 1.7 μm, etc.

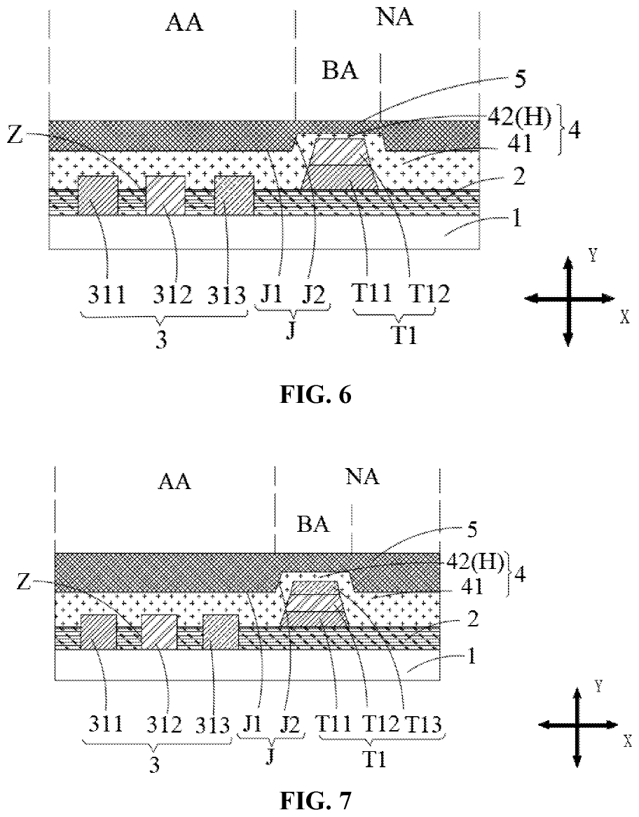

As shown in FIG. 6 which is another cross-sectional view of the display panel along the B-B direction in FIG. 1 and FIG. 7 which is another cross-sectional view of the display panel along the B-B direction in FIG. 1, in some embodiments, the color blocking structures 3 may include at least two types of color blockers 31 of different colors, and the first protruding structure T1 may be made of a material including at least one type of color blockers 31.

In the present embodiment, the first protruding structure T1 may be formed together with the color blockers 31 of one color through a same process, that is, the first protruding structure T1 may be made of a material same as the material of the color blockers 31 of this color. Therefore, the process may be simplified and the producing cost may be reduced, since it may be unnecessary to form the first protruding structure T1 with extra materials.

As shown in FIG. 6, in one embodiment, the color blocking structures 3 may at least include first color blockers 311 and second color blockers 312 of different colors. The first protruding structure T1 may include a first color blocker material layer T11 and a second color blocker material layer T12 stacked in a direction away from the substrate 1. The first color blockers 311 and the first color blocker material layer T11 may be prepared by the same process, and the second color blockers 312 and the second color blocker material layer T12 may be prepared by the same process, which facilitates preparation and reduces production costs.

Of course, in some other embodiments, the color blocking structures 3 may also include more color blockers 31 of different colors. For example, the color blocking structures 3 may include red color blockers 31, green color blockers 31 and blue color blockers 31, respectively corresponding to red light emission, green light emission and blue light emission of the display panel.

In one embodiment shown in FIG. 7, the color blocking structures 3 may at least include first color blockers 311, second color blockers 312 and third color blockers 313 with different colors. The first protruding structure T1 may include a first color blocker material layer T11, a second color blocker material layer T12, and a third color blocker material layer T13 stacked in the direction away from the substrate 1.

In the present embodiment, the first protruding structure T1 may be a single-layer structure formed by a material of color blockers 31 of a same color, or a stacked structure formed by multiple layers of materials of color blockers 31 of different colors. For example, the first protruding structure T1 may be a two-layer stacked structure including two color resist material layers, or the first protruding structure T1 may be a stacked structure including three color resist material layers stacked. There is no special limit on the number of color blocker material layers in the first protruding structure T1, as long as the height of the first protruding structure T1 meets the requirements.

The stacking sequence of each color blocker material layer in the first protruding structure T1 may correspond to the preparation sequence of the color blockers 31 of each color in the color blocking structures 3. For example, when the first color blockers 311 in the color blocking structures 3 are prepared first, the first color blocker material layer T11 of the first protruding structure T1 may be formed together. And then, the second color blockers 312 and the second color blocker material layer T12 may be formed simultaneously. That is, the first color blocker material layer T11 and the second color blocker material layer T12 may be sequentially stacked in the direction away from the substrate 1.

The color blocking structures 3 may be used to filter light to emit light of different colors. The different colors of the first color blockers 311 and the second color blockers 312 may specifically mean that the first color blockers 311 and the second color blockers 312 may filter light of different colors.

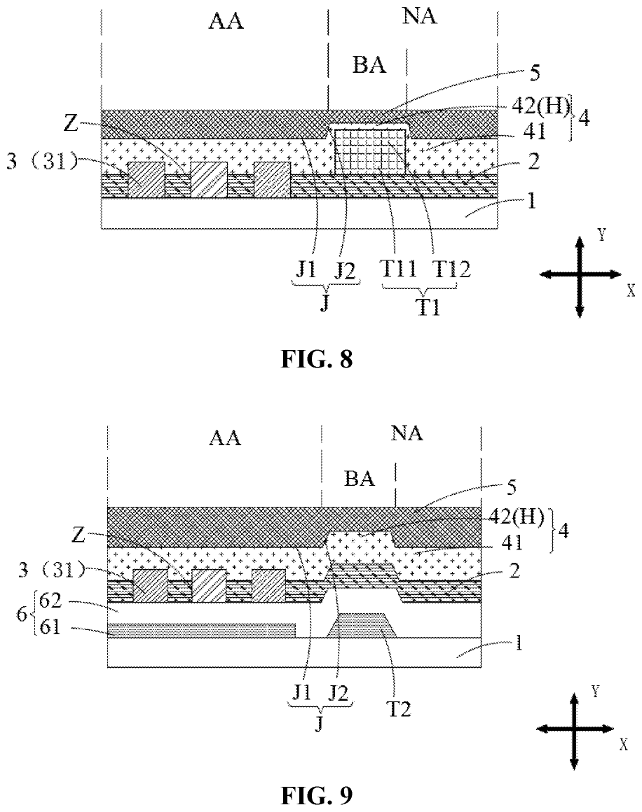

As shown in FIG. 7 and FIG. 8 which is another cross-sectional view of the display panel along the B-B direction in FIG. 1, in one embodiment, along the direction Y perpendicular to the plane of the substrate 1, the cross section of the first protruding structure T1 may be at least one of a rectangle, a trapezoid, or a triangle. Of course, in other embodiments, according to actual needs, the cross section of the first protruding structure T1 may adopt other shapes without special limitations.

As shown in FIG. 5, in some optional embodiments, in the direction X parallel to the plane of the substrate 1, the width b of the first protruding structure T1 may be larger than or equal to the width c of the color blockers 31.

When the width b of the first protruding structure T1 is larger, that is, when the width of the corresponding second portion J2 is larger, it may be easier to distinguish the first portion J1 and the second portion J2. In one embodiment, the width b of the first protruding structure T1 may be equal to the width c of the color blockers 31, to facilitate preparation of corresponding mask opening. In another embodiment, the width b of the first protruding structure T1 may be larger than the width c of the color blockers 31, such that the raised portion 42 formed correspondingly in the first functional layer 4 may be more obvious and easier to identify.

As shown in FIG. 9, which is another cross-sectional view of the display panel along the B-B direction in FIG. 1, in some embodiments, the display panel may further include a touch layer 6 between the substrate 1 and the light-shielding layer 2. In the direction Y perpendicular to the plane of the substrate 1, the touch layer 6 may at least include a conductive layer 61 and an insulating layer 62. In the boundary marking region BA, at least one of the conductive layer 61 or the insulating layer 62 may be provided with a second protruding structure T2. The first functional layer 4 may include a flat portion 41 and a raised portion 42 provided on the side of the second protruding structure T2 away from the substrate 1. The raised portion 42 may protrude in a direction away from the substrate 1 relative to the flat portion 41. The marking structure H may include the raised portion 42.

In this embodiment, since the touch layer 6 is disposed between the substrate 1 and the light-shielding layer 2, that is, the touch layer 6 is disposed under the first functional layer 4 and the second functional layer 5, by providing the second protruding structure T2 in at least one of the conductive layer 61 or the insulating layer 62, the first functional layer 4 may be provided with the raised portion 42 in the direction away from the substrate 1 at a position corresponding to the second protruding structure T2. The interface J between the raised portion 42 and the second functional layer 5 may correspond to the second portion J2, and the interface J between the flat portion 41 and the second functional layer 5 may correspond to the first portion J1. Since the raised portion 42 is convex relative to the flat portion 41, the interface J between the raised portion 42 and the second functional layer 5 may be not coplanar with the interface J between the flat portion 41 and the second functional layer 5. Correspondingly, the optical paths of the reflected light when the external light irradiates the raised portion 42 and the flat portion 41 may be different. Therefore, the amount of reflective light entering the human eye generated by the external light at the first portion J1 and the second portion J2 may be different, and it may be easier to identify the difference in the brightness/darkness levels of the second portion J2 corresponding to the raised portion 42 and the first portion J1 under external light irradiation.

In one embodiment, the second protruding structure T2 may be formed in the conductive layer 61. That is, the second protruding structure T2 may be made of a conductive material. The second protruding structure T2 may be insulated from other portions of the conductive layer 61, to avoid the influence on the signal transmission of the other portions of the conductive layer 61. In some other embodiments, the second protruding structure T2 may be formed together with the insulating layer 62 through a same process, and may be made of a material same as the insulating layer 62. The insulating layer 62 may be made of a material including silicon nitride, silicon oxide, SiNO, or a combination thereof.

In one embodiment, the conductive layer 61 may be used to set touch electrodes, touch wiring or other portions that require signal transmission. In some embodiments, according to the actual structure of the touch layer 6, one or more conductive layers 61 may be set. For example, in one embodiment, the touch layer 6 may adopt a self-capacitive structure, and one conductive layer 61 may be used to set the touch electrodes. In another embodiment, the touch layer 6 may adopt a mutual capacitance structure. When the driving touch electrodes and the sensing touch electrodes are arranged on the same layer, one conductive layer 61 may be used to set the driving touch electrodes and sensing touch electrodes. When the driving touch electrodes and the sensing touch electrodes are arranged in different layers, two or more conductive layers 61 may be used to arrange the driving touch electrodes and the sensing touch electrodes.

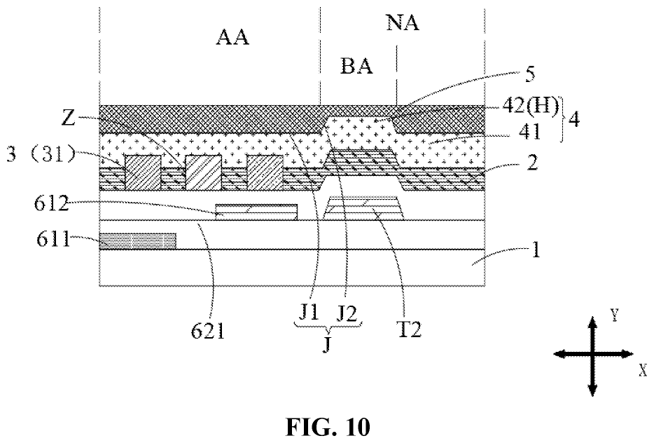

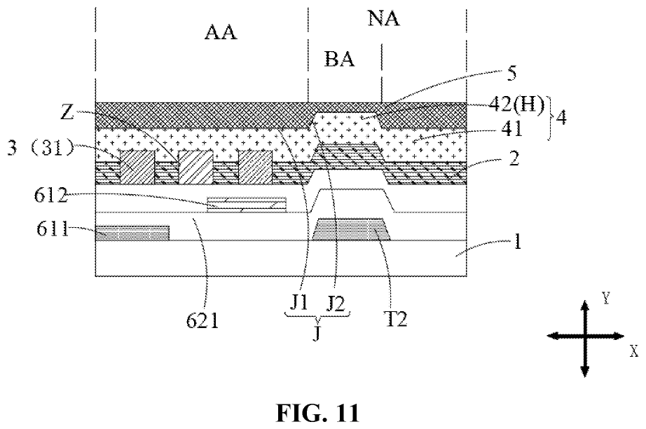

As shown in FIG. 10 which is another cross-sectional view of the display panel along the B-B direction in FIG. 1 and FIG. 11 which is another cross-sectional view of the display panel along the B-B direction in FIG. 1, in the direction Y perpendicular to the plane of the substrate 1, the touch layer 6 may include a first conductive layer 611, a first insulating layer 621 and a second conductive layer 612 stacked in the direction away from the substrate 1. The second protruding structure T2 may be provided in the same layer as any one of the first conductive layer 611, the first insulating layer 621, and the second conductive layer 612.

For example, in one embodiment shown in FIG. 11, the second protruding structure T2 and the first conductive layer 611 may be arranged on the same layer. The second protruding structure T2 and the first conductive layer 611 may be made of the same material. The second protruding structure T2 may be made of the material of the first conductive layer 611, and may protrude to a certain height away from the substrate 1 relative to the first conductive layer 611. Therefore, the first insulating layer 621, the light-shielding layer 2, and the first function layer 4 located on the second protruding structure T2 may protrude accordingly. That is, the raised portion 42 may be formed in the first functional layer 4.

In another embodiment shown in FIG. 10, the second protruding structure T2 and the second conductive layer 612 may be arranged in the same layer. The second protruding structure T2 may be made of the material of the second conductive layer 612 and may protrude to a certain height in the direction away from the substrate 1 compared to the first insulating layer 621. Therefore, the first insulating layer 621, the light-shielding layer 2, and the first function layer 4 located on the second protruding structure T2 may protrude accordingly. That is, the raised portion 42 may be formed in the first functional layer 4.

Optionally, the material of the second protruding structure T2 may include at least one of the materials of the first conductive layer 611, the first insulating layer 621, or the second conductive layer 612. The material of the second protruding structure T2 may be specifically selected according to the placement position of the second protruding structure T2, as long as it is easy to prepare. The second protruding structure T2 may be prepared together with any one of the first conductive layer 611, the first insulating layer 621 or the second conductive layer 612 through the same process.

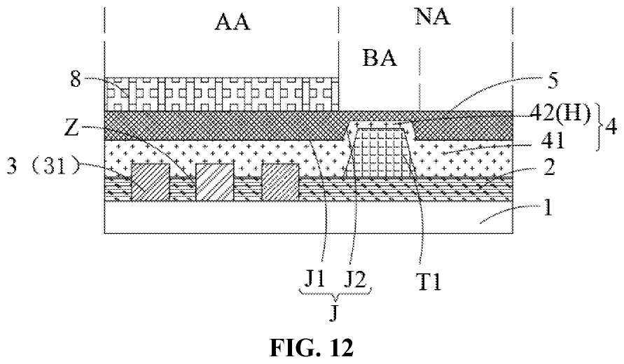

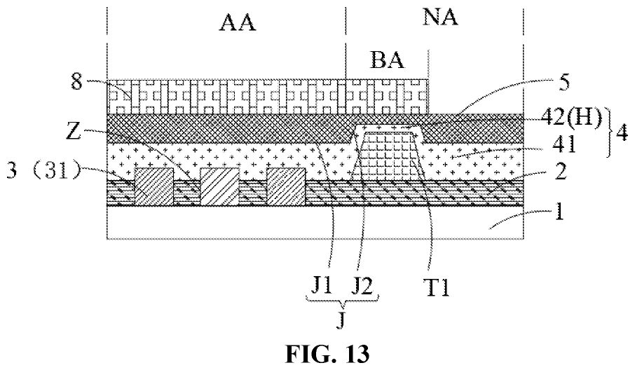

In one embodiment, as shown in FIG. 12, which is another cross-sectional view of the display panel along the B-B direction in FIG. 1, the display panel may further include a cover 8 on a side of the second functional layer 5 away from the substrate 1. The cover 8 may be located in the display region AA.

In one embodiment, the cover 8 may be made of a material including colorless polyimide (CPI). By observing the difference of the brightness/darkness level between the first portion J1 in the display region AA and the second portion J2 in the boundary marking region BA under the external light, the boundary position between the display region AA and the non-display region NA may be determined, and then the cover 8 may be disposed in the display region AA according to the boundary position.

In another embodiment, as shown in FIG. 13 which is another cross-sectional view of the display panel along the B-B direction in FIG. 1, the cover 8 may be disposed in the display region AA and the boundary marking region BA. The covering range of the cover 8 may be increased to improve the protection function of the cover 8.

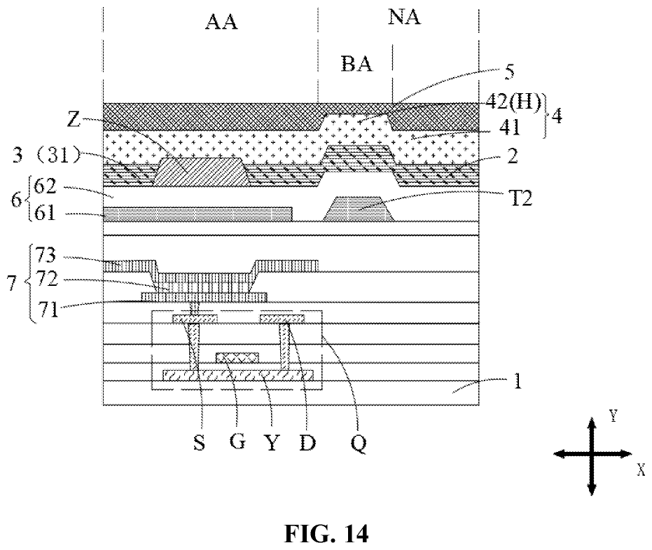

In one embodiment, as shown in FIG. 14, which is another cross-sectional view of the display panel along the B-B direction in FIG. 1, an array layer and a display layer 7 may be provided between the touch layer 6. The array layer may include pixel circuits. The display layer 7 may include a first electrode layer 71, a light-emitting layer 72 and a second electrode layer 73 stacked. The pixel circuits may include thin film transistors Q. Each thin film transistor Q may include an active layer Y, a gate G, a source S, and a drain D. The materials of the drain D, the source S, and the gate G may include one of molybdenum, titanium, aluminum, copper, etc. or a combination thereof. The gate G of the thin film transistor Q may be usually used to receive a control signal, such that the thin film transistor Q is turned on or off under the control of the control signal. One of the source S and the drain D of the thin film transistor Q may be connected to the first electrode layer 71 to control normal light emission of the light-emitting layer 72.

Optionally, a film layer, such as an encapsulation layer (not shown in the figure), may also be provided between the display layer 7 and the touch layer 6, without special limitations.

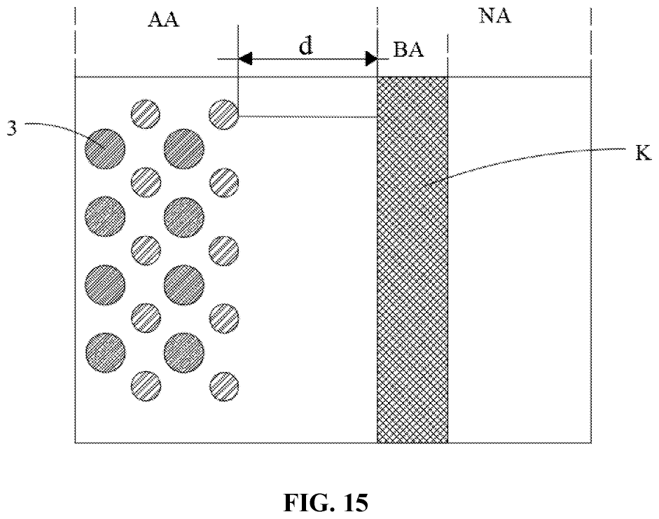

In some embodiments shown in FIG. 15 which is a partially enlarged view of pint C in FIG. 1, in the direction X parallel to the plane of the substrate 1, a minimum distance d between the boundary marking region BA and the color blocking structures 3 may be larger than or equal to 2 μm.

In this embodiment, the minimum distance d between the boundary marking region BA and the color resistance structures 3 may be understood as the distance between the boundary marking region BA and one nearest color resistance structure 3. Since the marking structure H needs to be set correspondingly in the boundary marking region and the marking structure H may adopt a convex structure or a groove structure, to avoid the negative impact of the marking structure H on the flatness of the color resist structures 3, the boundary marking region BA may need to be prevented from being too close to the color resistance structures 3. Therefore, in this embodiment, the minimum distance d between the boundary marking region BA and the color resistance structures 3 may be set to be larger than or equal to 2 μm. For example, the minimum distance d between the boundary marking region BA and the color resistance structures 3 may be set to 2 μm, 4 μm, 6 μm, etc.

The present disclosure also provides a display device. The display device may include a display panel provided by various embodiments of the present disclosure.

The display device in various embodiments may be an organic light-emitting diode (OLED) display device, a quantum dot light-emitting diode (QLED) display device, or a micro-OLED/LED display device.

The display device provided by the present disclosure may be applied to a cell phone or any other electronic products with display functions, including but not limited to: TVs, laptops, desktop monitors, tablets, digital cameras, smart bracelets, smart glasses, vehicle monitors, medical equipment, industrial control equipment, or touch interactive terminals.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above-described embodiments, the present disclosure is not limited to the above described embodiments, but may be embodied in other equivalent forms without departing from the scope of the present disclosure, which is determined by the appended claims.

What is claimed is:

1. A display panel, comprising:
a display region and a non-display region adjacent to the display region, the non-display region including a boundary marking region and the boundary marking region including a marking structure;
a substrate;
a light-shielding layer on a side of the substrate and located in the display region and the non-display region, wherein the light-shielding layer includes light-shielding layer openings in the display region;
a color blocking structure, arranged corresponding to the light-shielding layer openings and located in the display region; and
a first functional layer and a second functional layer,
wherein:
the first functional layer and the second functional layer are arranged on a side of the light-shielding layer away from the substrate in a direction away from the substrate;
there is an interface between the first functional layer and the second functional layer;
the interface includes a first portion and a second portion;
the second portion is distributed corresponding to the boundary marking region; and
the second portion is not coplanar with the first portion.

2. The display panel according to claim 1, wherein:
the marking structure includes a groove provided in the first functional layer, and the second functional layer is filled in the groove.

3. The display panel according to claim 2, wherein:
in a direction from the substrate to the first functional layer, the groove is gradually expanded.

4. The display panel according to claim 2, wherein:
in a direction perpendicular to a plane of the substrate, a cross section of the groove is at least one of a rectangle, an inverted trapezoid, or a triangle.

5. The display panel according to claim 2, wherein:
the groove includes a first side, and an angle between the first side and the plane of the substrate is about 60° to about 90°.

6. The display panel according to claim 1, wherein:
a first protruding structure is provided on the side of the light-shielding layer away from the substrate;
the first protruding structure is located in the boundary marking region;
the first functional layer includes a flat portion and a raised portion on a side of the first protruding structure away from the substrate;
the raised portion protrudes toward a direction away from the substrate relative to the flat portion; and
the marking structure includes the raised portion.

7. The display panel according to claim 6, wherein:
in a direction perpendicular to a plane of the substrate, a height difference between a surface of a side of the raised portion away from the substrate and a surface of a side of the flat portion away from the substrate is larger than or equal to 1.5 μm.

8. The display panel according to claim 6, wherein:
the color blocking structure includes at least two types of color blockers of different colors, and the first protruding structure is made of a material including at least one of the at least two types of color blockers.

9. The display panel according to claim 6, wherein:
the color blocking structure at least includes first color blockers and second color blockers of different colors;
the first protruding structure includes a first color blocker material layer and a second color blocker material layer stacked in a direction away from the substrate;
the first color blockers and the first color blocker material layer are prepared through a same process, and
the second color blockers and the second color blocker material layer are prepared through a same process.

10. The display panel according to claim 6, wherein:
in a direction parallel to the plane of the substrate, a width of the first protruding structure is larger than or equal to a width of the color blocking structure.

11. The display panel according to claim 6, wherein:
in a direction from the substrate to the first functional layer, the first protruding structure is tapered gradually.

12. The display panel according to claim 6, wherein:
in a direction perpendicular to a plane of the substrate, a cross-section of the first protruding structure is at least one of a rectangle, a trapezoid, or a triangle.

13. The display panel according to claim 1, further including a touch layer between the substrate and the light-shielding layer, wherein:
in a direction perpendicular to a plane of the substrate, the touch layer includes at least one conductive layer and an insulating layer;
in the boundary marking region, at least one of the at least one conductive layer or the insulating layer is provided with a second protruding structure;
the first functional layer includes a flat portion and a raised portion provided on a side of the second protruding structure away from the substrate;
the raised portion protrudes toward a direction away from the substrate relative to the flat portion; and
the marking structure includes the raised portion.

14. The display panel according to claim 13, wherein:
the touch layer includes a first conductive layer, a first insulating layer, and a second conductive layer, that are stacked in a direction away from the substrate; and
the second protruding structure is disposed in a layer same as at least one of the first conductive layer, the first insulating layer, or the second conductive layer.

15. The display panel according to claim 14, wherein:
the second protruding structure is made of a material including at least one of the first conductive layer, the first insulating layer, or the second conductive layer.

16. The display panel according to claim 1, further including a cover on a side of the second functional layer away from the substrate, wherein:
the cover is located in the display region, or the cover is located in the display region and the boundary marking region.

17. The display panel according to claim 1, wherein:
in a direction parallel to a plane of the substrate, a minimum distance between the boundary marking region and the color blocking structure is larger than or equal to 2 μm.

18. A display device, comprising:
a display panel that includes a display region and a non-display region adjacent to the display region, wherein the non-display region includes a boundary marking region and the boundary marking region includes a marking structure, the display panel further comprising:
a substrate;
a light-shielding layer on a side of the substrate and located in the display region and the non-display region, wherein the light-shielding layer includes light-shielding layer openings in the display region;
a color blocking structure, arranged corresponding to the light-shielding layer openings and located in the display region; and
a first functional layer and a second functional layer,
wherein:
the first functional layer and the second functional layer are arranged on a side of the light-shielding layer away from the substrate in a direction away from the substrate;
there is an interface between the first functional layer and the second functional layer;
the interface includes a first portion and a second portion;
the second portion is distributed corresponding to the boundary marking region; and
the second portion is not coplanar with the first portion.
